(19) United States
(12) Patent Application Publication
(10) Pub. No.: US 2025/0275426 A1
(43) Pub. Date: Aug. 28, 2025

(54) DISPLAY DEVICE

(71) Applicant: SAMSUNG DISPLAY CO., LTD., YONGIN-SI (KR)

(72) Inventors: Jeong Seok LEE, Yongin-si (KR); Oh June KWON, Yongin-si (KR); Hyo Jeong KWON, Yongin-si (KR); Soo Youn KIM, Yongin-si (KR); Woo Yong SUNG, Yongin-si (KR); Hee Jun YANG, Yongin-si (KR); Soo Min OH, Yongin-si (KR); Jin Ho HYUN, Yongin-si (KR); Sang Yeon HWANG, Yongin-si (KR)

(21) Appl. No.: 18/944,085

(22) Filed: Nov. 12, 2024

(30) Foreign Application Priority Data
Feb. 27, 2024 (KR) 10-2024-0027978

(51) Int. Cl. H10K 59/80; H10K 102/00

(52) U.S. Cl. CPC H10K 59/873; H10K 2102/351

(57) ABSTRACT

A display device includes a panel layer including a first area and a second area. A support layer is disposed on a first surface of the panel layer. At least a portion of the panel layer is bendable in the second area. The support layer overlaps with the second area in a plan view. The support layer has a storage modulus in a range of about 0.01 Mpa to about 0.1 Mpa in an area that the support layer overlaps with the second area in the plan view.

### CROSS-REFERENCE TO RELATED APPLICATION

The present application claims priority under 35 U.S.C. § 119(a) to Korean Patent Application No. 10-2024-0027978, filed on Feb. 27, 2024 in the Korean Intellectual Property Office, the disclosure of which is incorporated by reference in its entirety herein.

### 1. Technical Field

The disclosure generally relates to a display device.

### 2. Discussion of Related Art

A display device is an electronic device that generates images to a user and serves as a connection medium providing the user with information. The importance of display devices has increased along with the development of information technologies. Accordingly, research and development of display devices have been continuously conducted.

A display device may include a panel layer having at least a portion that is bendable and a support layer which supports the panel layer. As the display device includes the at least partially bendable panel layer, at least a portion of the display device may be bent (e.g., is bendable). Accordingly, the display device can be easily carried, thereby increasing user convenience.

However, when the support layer is not properly formed, cracks may occur in the support layer when the panel layer is bent, and therefore, a defect rate of the display device may be increased.

### SUMMARY

An aspect of an embodiment of the present disclosure is providing a display device having a decreased defect rate.

In accordance with an embodiment of the present disclosure, a display device includes a panel layer including a first area and a second area. A support layer is disposed on a first surface of the panel layer. At least a portion of the panel layer is bendable in the second area. The support layer overlaps with the second area in a plan view. The support layer has a storage modulus in a range of about 0.01 Mpa to about 0.1 Mpa in an area that the support layer overlaps with the second area in the plan view.

In an embodiment, the panel layer may include a second surface opposite to the first surface. The panel layer may include an encapsulation layer including a surface corresponding to the second surface. A display image generated by the display device is displayed on the second surface of the panel layer.

In an embodiment, the encapsulation layer may be disposed at an outermost portion of the panel layer.

In an embodiment, the encapsulation layer may have a first thickness in an area that the encapsulation overlaps with the first area in the plan view and a second thickness in an area that the encapsulation layer overlaps with the second area in the plan view. The first thickness may be in a range of about 8.8 [symbol] to about 15 [symbol] , and the second thickness may be in a range of about 1 [symbol] to about 8.8 [symbol] .

In an embodiment, the encapsulation layer may have a first thickness in an area that the encapsulation overlaps with the first area in the plan view and a second thickness equal to the first thickness in an area that the encapsulation layer overlaps with the second area in the plan view. Each of the first thickness and the second thickness may be in a range of about 1 [symbol] to about 8.8 [symbol] .

In an embodiment, the support layer may overlap with the first area and the second area in the plan view.

In an embodiment, the support layer may not overlap with the first area in the plan view.

In an embodiment, the support layer may include an organic material. The support layer further include at least one material selected from a heat dissipation material and a light blocking material.

In an embodiment, the organic material may include at least one material selected from silicon-based resin, phenol-based resin, acryl-based resin, methacryl-based resin, vinyl-based resin, epoxy-based resin, urethane-based resin, cellulose-based resin, parylene-based resin, and polyisoprene-based resin. The heat dissipation material may include at least one compound selected from Ag, Cu, Al, Al₂O₃, Mg, Ti, and Au. The light blocking material may include at least one of carbon black, graphene, carbon nano tubes, and fullerene.

In an embodiment, the support layer is applied on the first surface through a printing process.

In an embodiment, the support layer may be applied and cured on the panel layer. The support layer is disposed directly on the panel layer.

According to an embodiment of the present disclosure, a display device includes a panel layer including a first area and a second area. A support layer is disposed on a first surface of the panel layer. A window is disposed on a second surface of the panel layer opposite to the first surface of the panel layer. The panel layer includes an encapsulation layer including a surface corresponding to the second surface. At least a portion of the panel layer is bendable in the second area. The support layer overlaps with the second area in a plan view. The encapsulation layer has a thickness in a range of about 1 [symbol] to about 8.8 [symbol] in an area that the encapsulation layer overlaps with the second area in the plan view.

In an embodiment, the encapsulation layer may be disposed at an outermost portion of the panel layer.

In an embodiment, the support layer may have a storage modulus in a range of about 0.01 Mpa to about 0.1 Mpa in an area that the support layer overlaps with the second area in the plan view. The support layer may overlap with both the first area and the second area in the plan view.

In an embodiment, the support layer may have a storage modulus in a range of about 0.01 Mpa to about 0.1 Mpa in an area that the support layer overlaps with the second area in the plan view. The support layer may not overlap with the first area in the plan view.

In an embodiment, the support layer may include an organic material, and further include at least one of a heat dissipation material and a light blocking material. The organic material may include at least one material selected from silicon-based resin, phenol-based resin, acryl-based resin, methacryl-based resin, vinyl-based resin, epoxy-based resin, urethane-based resin, cellulose-based resin, parylene-based resin, and polyisoprene-based resin. The heat dissipation material may include at least one compound selected from Ag, Cu, Al, Al₂O₃, Mg, Ti, and Au. The light blocking material may include at least one of carbon black, graphene, carbon nano tubes, and fullerene.

In an embodiment, the support layer may be applied on the first surface through a printing process. The support layer is disposed directly on the panel layer.

According to an embodiment of the present disclosure, a display device includes a panel layer including a first area and a second area. A support layer is disposed on a first surface of the panel layer. A window is disposed on a second surface of the panel layer opposite to the first surface of the panel layer. The panel layer includes an encapsulation layer including a surface corresponding to the second surface. At least a portion of the panel layer is bendable in the second area. The support layer includes a first support layer disposed on the first surface. A second support layer is disposed on the first support layer. The second support layer includes at least one of a light blocking material and a heat dissipation material. The support layer has a storage modulus in a range of about 0.01 Mpa to about 0.1 Mpa in an area that the support layer overlaps with the second area in a plan view. The encapsulation layer has a thickness in a range of about 1 [symbol] to about 8.8 [symbol] in an area that the encapsulation layer overlaps with the second area in the plan view.

In an embodiment, the second support layer may be attached on the first support layer through a lamination process after the first support layer is bent.

In an embodiment, the first support layer may include a first portion overlapping with the first area in the plan view. A second portion overlaps with the second area in the plan view. The first portion may include polyethylene terephthalate. The panel layer may have a flat surface in the first area.

### BRIEF DESCRIPTION OF THE DRAWINGS

Non-limiting embodiments of the present disclosure will now be described more fully hereinafter with reference to the accompanying drawings; however, the present disclosure may be embodied in different forms and should not be construed as limited to the described embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the present disclosure.

FIG. 2 is a schematic perspective view illustrating the display device in accordance with an embodiment of the present disclosure.

FIG. 3 is a schematic plan view of the display device shown in FIG. 2 in accordance with an embodiment of the present disclosure.

FIG. 4 is a cross-sectional view schematically illustrating a stacked structure of the display device in accordance with an embodiment of the present disclosure.

FIG. 5 is a cross-sectional view schematically illustrating a stacked structure of a panel layer in accordance with an embodiment of the present disclosure.

FIGS. 6 and 7 are schematic cross-sectional views of encapsulation layers in accordance with embodiments of the present disclosure.

FIGS. 8 and 9 are schematic cross-sectional views of support layers in accordance with embodiments of the present disclosure.

FIG. 10 is a cross-sectional view schematically illustrating a stacked structure of the display device in accordance with an embodiment of the present disclosure.

FIGS. 11 and 12 are schematic cross-sectional views of support layers in accordance with embodiments of the present disclosure.

### DETAILED DESCRIPTION OF EMBODIMENTS

Embodiments of the present disclosure may apply various changes and different shapes to the described embodiments and embodiments of the present disclosure are not necessarily limited to certain shapes but include all changes and equivalent materials and replacements. The drawings included may be illustrated in a fashion where the elements are expanded or exaggerated for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Embodiments of the present disclosure generally relates to a display device. Hereinafter, a display device in accordance with an embodiment of the present disclosure will be described with reference to the accompanying drawings.

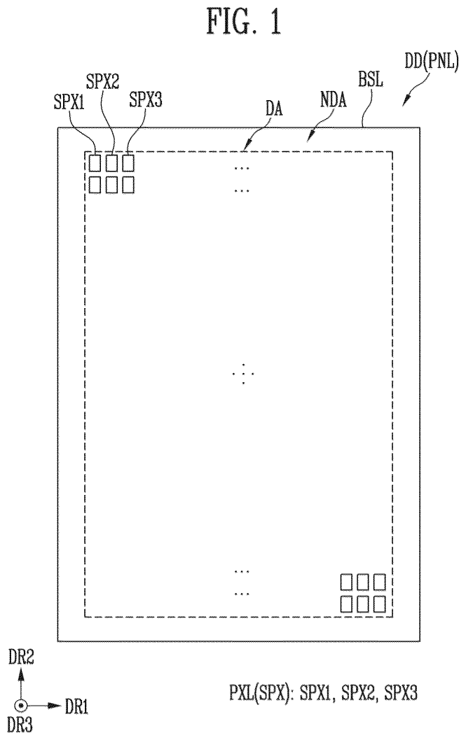

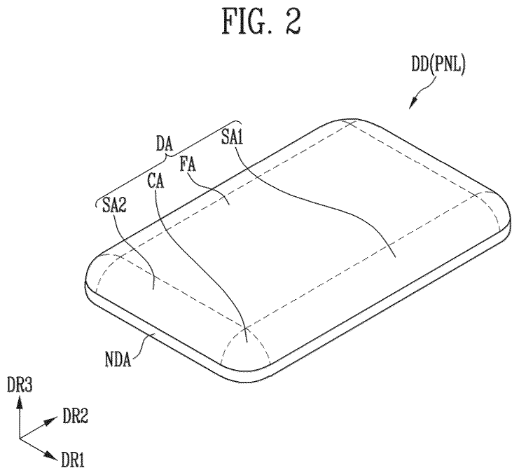

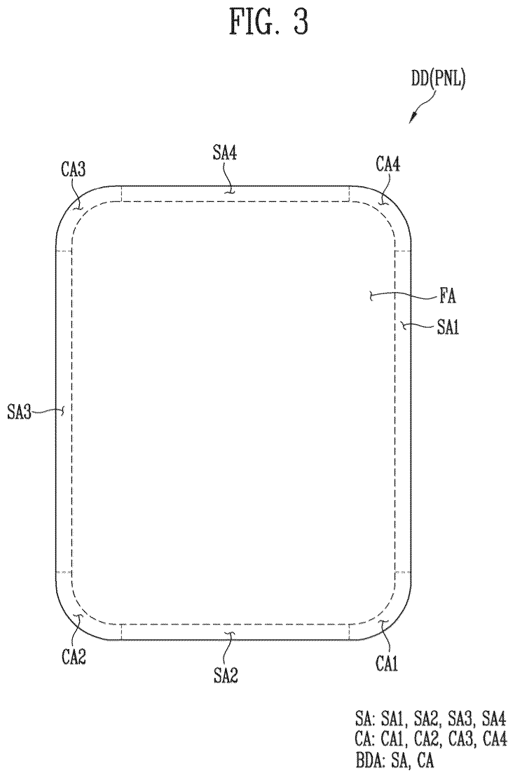

FIG. 1 is a schematic plan view illustrating a display device in accordance with an embodiment of the present disclosure. FIG. 2 is a schematic perspective view illustrating the display device in accordance with an embodiment of the present disclosure. FIG. 3 is a schematic plan view of the display device shown in FIG. 2.

Referring to FIGS. 1 to 3, the display device DD is configured to emit light. The display device DD includes a light emitting element LD (see FIG. 5). In some embodiments, the display device DD may be a display device for displaying at least one moving image and/or still image. The display device DD may be used as a display screen of not only portable electronic devices, such as a mobile phone, a smart phone, a tablet personal computer (PC), a mobile communication terminal, an electronic notebook, an electronic book, a portable multimedia player (PMP), a navigation system, and an ultra-mobile PC, but also various products such as a television, a notebook computer, a monitor, an advertisement board, and Internet of things (IoT).

In an embodiment, the display device DD may be formed in a rectangular plane having relatively short sides in a first direction DR1 and relatively long sides in a second direction DR2 intersecting the first direction DR1. In some embodiments, a corner at which the relatively short side in the first direction DR1 and the relatively long side in the second direction DR2 meet each other may be formed round to have a predetermined curvature or be formed at a right angle. However, the planar shape of the display device DD is not necessarily limited to a quadrangular shape, and the display device DD may be formed in another polygonal shape or a round shape such as a circular shape or an elliptical shape. In an embodiment, the display device DD may be formed flat. However, embodiments of the present disclosure are not necessarily limited thereto. For example, in some embodiments the display device DD may include a curved portion which is formed at left/right ends and has a constant curvature or a changing curvature. In addition, the display device DD may be formed flexible enough to be warpable, curvable, bendable, foldable or rollable. In some embodiments, the display device DD may be a flexible display device.

In the present disclosure, the first direction DR1 may be a “horizontal” direction as a row direction of pixels PXL. The second direction DR2 may be a column direction of pixels PXL. A third direction DR3 may be a display direction of the display device DD or a normal direction of a plane on which a base layer BSL is disposed. While the first direction DR1, the second direction DR2 and the third direction DR3 may be perpendicular to each other, embodiments of the present disclosure are not necessarily limited thereto and the first to third directions DR1 to DR3 may cross each other at various different angles.

The display device DD may include a display area DA and a non-display area NDA. The non-display area NDA may mean an area except the display area DA. The non-display area NDA may surround at least a portion of the display area DA (e.g., in the first and/or second directions DR1, DR2).

The display area DA may mean an area in which pixels PXL are disposed. The display area DA may include a front area FA, side areas SA disposed at the periphery of the front area FA, and corner areas disposed between two adjacent side areas.

For example, in an embodiment the side areas SA may include a first side area SA1 disposed at a first side (e.g., a right side in the first direction DR1) of the front area FA, a second side area SA2 disposed at a second side (e.g., a lower side in the direction opposite to the second direction DR2) of the front area FA, a third side surface SA3 disposed at a third side (e.g., a left side in the direction opposite to the first direction DR1) of the front area FA, and a fourth side area SA4 disposed at a fourth side (e.g., an upper side in the second direction DR2) of the front area FA.

For example, as shown in an embodiment of FIG. 3, corner areas CA may include a first corner area CA1 disposed between the first side area SA1 and the second side area SA2, a second corner area CA2 disposed between the second side area SA2 and the third side area SA3, a third corner area CA3 disposed between the third side area SA3 and the fourth side area SA4, and a fourth corner area CA4 disposed between the fourth side area SA4 and the first side area SA1.

In FIG. 3, it is illustrated that each of the numbers of the corner areas CA and the side areas SA is four (e.g., in a plan view). However, embodiments of the present disclosure are not necessarily limited thereto. For example, in some embodiments, the numbers of the corner areas CA and the side areas SA may be less than four or greater than four.

The display device DD, such as a panel layer PNL, may have a roughly flat surface in the front area FA. For example, the panel layer PNL may not be bent in the front area FA, and the front area FA may be defined as a first area or a flat area (e.g., a flat portion).

In an embodiment, the display device DD may have a curved surface in each of the side areas SA and the corner areas CA. For example, at least a portion of the panel layer PNL may be bent in the side areas SA and the corner areas CA, and the side areas SA and the corner areas CA may be defined as a second area or a bending area (e.g., a bending portion) BDA.

The non-display area NDA may mean an area in which the pixels PXL are not disposed. In an embodiment, the non-display area NDA may be defined along edges of the side areas SA and the corner areas CA. In an embodiment, a driving circuit, lines, and pads, which are connected to the pixels PXL of the display area DA, may be disposed in the non-display area NDA.

In some embodiments, the pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel unit capable of emitting lights of various colors. In FIG. 1, it is shown that each pixel PXL includes three sub-pixels SPX1, SPX2, such as the first sub-pixel SPX1, the second sub-pixel SPX2, and the third sub-pixel SPX3. However, embodiments of the present disclosure are not necessarily limited thereto.

In some embodiments, the pixels PXL (or sub-pixels SPX) may be arranged according to a stripe arrangement structure, a PENTILE™ arrangement structure, or the like. However, embodiments of the present disclosure are not necessarily limited thereto.

The first sub-pixel SPX1 may emit first light, the second sub-pixel SPX2 may emit second light, and the third sub-pixel SPX3 may emit third light. In an embodiment, the first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm. However, embodiments of the present disclosure are not necessarily limited thereto and the colors emitted by the first to third sub-pixels SPX1 to SPX3 may vary.

In an embodiment, each of the first sub-pixel SPX1, the second sub-pixel SPX2, and the third sub-pixel SPX3 may include an inorganic light emitting element including an inorganic material emitting light or an organic light emitting element including an organic material emitting light. For example, the light emitting element LD may be micro Light Emitting Diode (LED) as an inorganic light emitting element including an inorganic semiconductor. However, embodiments of the present disclosure are not necessarily limited thereto. For example, in some embodiments, the light emitting element LD may be an Organic Light Emitting Diode (OLED) including an organic material. Hereinafter, for convenience of explanation, an embodiment (see FIG. 5) in which the light emitting element LD is an organic light emitting element is illustrated.

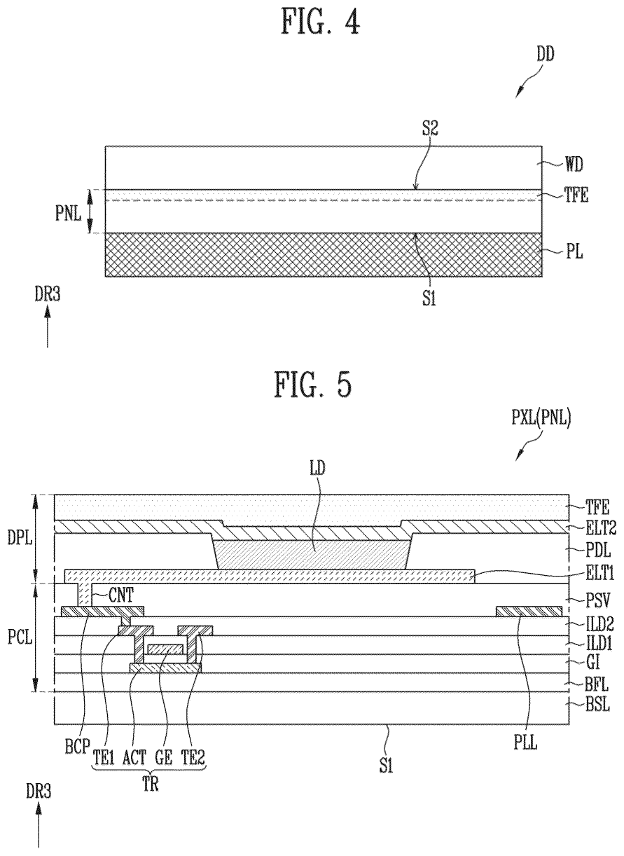

FIG. 4 is a cross-sectional view schematically illustrating a stacked structure of the display device in accordance with an embodiment of the present disclosure. FIG. 5 is a cross-sectional view schematically illustrating a stacked structure of a panel layer in accordance with an embodiment of the present disclosure. FIG. 5 may be a schematic cross-sectional view illustrating a panel PNL included in a pixel PXL in accordance with an embodiment of the present disclosure. FIG. 5 is an embodiment in which the panel layer PNL is an organic light emitting display panel, and schematically illustrates a cross-sectional structure of the pixel PXL (e.g., any one of sub-pixels SPX1, SPX2, and SPX3).

Referring to FIG. 4, in an embodiment the display device DD may include a panel layer PNL, a support layer PL, and a window WD.

The support layer PL may be disposed on (e.g., disposed directly thereon) a first surface S1 of the panel layer PNL. The first surface S1 of the panel layer PNL may be a bottom surface (e.g., a rear surface) of the panel layer PNL. The first surface S1 of the panel layer PNL may be an opposite surface of a surface, such as a second surface S2, on which a display image generated by the display device DD is displayed. Hereinafter, in the disclosure, when the stacked structure of the display device DD is described, a lower direction may be defined as the opposite direction of the third direction DR3, and an upper direction may be defined as the third direction DR3.

The support layer PL may support the panel layer PNL. For example, in an embodiment the support layer PL may protect and support the panel layer PNL when a module process is performed after the panel layer PNL is formed. For example, the module process may be a process of connecting the panel layer PNL to a driving circuit of the display device DD.

In an embodiment, the support layer PL may have at least one characteristic among a light blocking characteristic, an impact resistance characteristic, and a heat dissipation characteristic. For example, the support layer PL may have at least one characteristic among the light blocking characteristic, the impact resistance characteristic, and the heat dissipation characteristic while supporting the panel layer PNL.

In an embodiment, the panel layer PNL may include a base layer BSL, a pixel circuit layer PCL, and a display element layer DPL.

The base layer BSL may provide an area in which the pixel circuit layer PCL and the display element layer DPL are disposed thereon. The base layer BSL may form (e.g., constitute) a base member of the pixel PXL. In an embodiment, the base layer BSL may be a rigid or flexible substrate or film. However, embodiments of the present disclosure are not necessarily limited to a specific example.

The pixel circuit layer PCL may be disposed on the base layer BSL (e.g., disposed directly thereon in the third direction DR3). In an embodiment, the pixel circuit layer PCL may include a buffer layer BFL, a transistor TR, a gate insulating layer GI, a first interlayer insulating layer ILD1, a second interlayer insulating layer ILD2, a connection pattern BCP, a power line PLL, a protective layer PSV and a contact portion CNT.

The buffer layer BFL may be disposed on the base layer BSL (e.g., disposed directly thereon in the third direction DR3). The buffer layer BFL may prevent an impurity from being diffused from the outside. In an embodiment, the buffer layer BFL may include at least one of silicon nitride (SiNₓ), silicon oxide (SiOₓ), silicon oxynitride (SiOxNy), and a metal oxide such as aluminum oxide (AlOₓ).

The transistor TR may be a thin film transistor. In an embodiment, the transistor TR may be a driving transistor. The transistor TR may be electrically connected to a light emitting element LD. The transistor TR may be electrically connected to the connection pattern BCP.

In an embodiment, the transistor TR may include an active layer ACT, a first transistor electrode TE1, a second transistor electrode TE2, and a gate electrode GE.

The active layer ACT may be a semiconductor layer. The active layer ACT may be disposed on the buffer layer BFL (e.g., disposed directly thereon in the third direction DR3). For example, in an embodiment the active layer ACT may include at least one of poly-silicon, Low Temperature Polycrystalline Silicon (LTPS), amorphous silicon, and an oxide semiconductor.

The active layer ACT may include a first contact region in direct contact with the first transistor electrode TE1 and a second contact region in direct contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be disposed on the gate insulating layer GI (e.g., disposed directly thereon in the third direction DR3). A position of the gate electrode GE may correspond to a position of the channel region of the active layer ACT. For example, the gate electrode GE may be disposed on the channel region of the active layer ACT with the gate insulating layer GI interposed therebetween (e.g., in the third direction DR3).

The gate insulating layer GI may be disposed over (e.g., disposed directly thereon) the active layer ACT. The gate insulating layer GI may include an inorganic material. In an embodiment, the gate insulating layer GI may include at least one of silicon nitride (SiNₓ), silicon oxide (SiOₓ), silicon oxynitride (SiOₓN_{y}), and aluminum oxide (AlOₓ).

The first interlayer insulating layer ILD1 may be located over (e.g., disposed directly thereon) the gate electrode GE. In an embodiment, similar to the gate insulating layer GI, the first interlayer insulating layer ILD1 may include at least one of silicon nitride (SiNₓ), silicon oxide (SiOₓ), silicon oxynitride (SiOₓN_{y}), and aluminum oxide (AlOₓ).

The first transistor electrode TE1 and the second transistor electrode TE2 may be located on the first interlayer insulating layer ILD1 (e.g., disposed directly thereon in the third direction DR3). The first transistor electrode TE1 may be in direct contact with the first contact region of the active layer ACT while penetrating the gate insulating layer GI and the first interlayer insulating layer ILD1 (e.g., in the third direction DR3), and the second transistor electrode TE2 may be in direct contact with the second contact region of the active layer ACT while penetrating the gate insulating layer GI and the first interlayer insulating layer ILD1 (e.g., in the third direction DR3). In an embodiment, the first transistor electrode TE1 may be a drain electrode, and the second transistor electrode TE2 may be a source electrode. However, embodiments of the present disclosure are not necessarily limited thereto.

The second interlayer insulating layer ILD2 may be located over (e.g., disposed directly thereon) the first transistor electrode TE1 and the second transistor electrode TE2. In an embodiment, similar to the first interlayer insulating layer ILD1 and the gate insulating layer GI, the second interlayer insulating layer ILD2 may include an inorganic material. For example, the inorganic material may include at least one of the materials described as the material constituting the first interlayer insulating layer ILD1 and the gate insulating layer GI, such as silicon nitride (SiNₓ), silicon oxide (SiOₓ), silicon oxynitride (SiOₓN_{y}), and aluminum oxide (AlOₓ).

The connection pattern BCP may be disposed on the second interlayer insulating layer ILD2 (e.g., disposed directly thereon in the third direction DR3). In an embodiment, the connection pattern BCP may be connected to (e.g., directly connected thereto) the first transistor electrode TE1 through a contact hole penetrating the second interlayer insulating layer TLD2. The connection pattern BCP may be electrically connected to a first electrode ELT1 through the contact portion CNT formed in the protective layer PSV.

The power line PLL may be disposed on the second interlayer insulating layer ILD2 (e.g., disposed directly thereon in the third direction DR3). In an embodiment, the power line PLL may be electrically connected to a second electrode ELT2 through another contact portion formed in the protective layer PSV.

The protective layer PSV may be located on the second interlayer insulating layer ILD2 (e.g., disposed directly thereon in the third direction DR3). The protective layer PSV may cover the connection pattern BCP and the power line PLL. In an embodiment, the protective layer PSV may be provided in a form including an organic insulating layer, an inorganic insulating layer, or the organic insulating disposed on the inorganic insulating layer. However, embodiments of the present disclosure are not necessarily limited thereto. In an embodiment, the contact portion CNT connected to one area of the connection pattern BCP and another contact portion connected to one area of the power line PLL may be formed in the protective layer PSV.

The display element layer DPL may be disposed on the pixel circuit layer PCL (e.g., disposed directly thereon in the third direction DR3). In an embodiment, the display element layer DPL may include the first electrode ELT1, the light emitting element LD, a pixel defining layer PDL, the second electrode ELT2, and an encapsulation layer TFE.

In an embodiment, the light emitting element LD may be disposed in an area defined by the pixel defining layer PDL. One surface (e.g., an upper surface in the third direction DR3) of the light emitting element may be connected to the first electrode ELT1, and the other surface (e.g., a lower surface in the direction opposite to the third direction DR3) of the light emitting element LD may be connected to the second electrode ELT2.

The first electrode ELT1 may be an anode electrode of the light emitting element LD, and the second electrode ELT2 may be a common electrode (e.g., a cathode electrode) of the light emitting element LD. In an embodiment, the first electrode ELT1 and the second electrode ELT2 may include a conductive material. For example, the first electrode ELT1 may include a conductive material having reflectivity, and the second electrode ELT2 may include a transparent conductive material. However, embodiments of the present disclosure are not necessarily limited thereto.

In an embodiment, the light emitting element LD may have a multi-layer thin film structure including a light generation layer. In an embodiment, the light emitting element LD may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. The light emitting element LD may release light, based on electrical signals provided from the first electrode ELT1 and the second electrode ELT2.

The pixel defining layer PDL may define a position at which the light emitting element LD implemented as an organic light emitting diode is arranged. For example, in an embodiment, the pixel defining layer PDL may cover lateral edges of the first electrode ELT1 and the light emitting element LD may be disposed in an opening of the pixel defining layer PDL overlapping a central portion of the first electrode ELT1. The pixel defining layer PDL may include an organic material. In an embodiment, the pixel defining layer PDL may include at least one of acrylic resin, epoxy resin, phenolic resin, polyamide resin, and polyimide resin. However, embodiments of the present disclosure are not necessarily limited thereto.

The encapsulation layer TFE may be disposed over the second electrode ELT2 (e.g., disposed directly thereon in the third direction DR3). The encapsulation layer TFE may planarize a step difference generated by the light emitting element LD and the pixel defining layer PDL. The encapsulation layer TFE may include a plurality of insulating layers covering the light emitting element LD. In an embodiment, the encapsulation layer TFE may have a structure in which an inorganic layer and an organic layer are alternately stacked. However, embodiments of the present disclosure are not necessarily limited thereto and the encapsulation layer TFE may include at least one inorganic layer and at least one organic layer in various different configurations.

In an embodiment the encapsulation layer TFE is a component disposed on the bottom of the window WD (e.g., in a direction opposite to the third direction DR3), and may mean a layer disposed at an outermost portion of the panel layer PNL. For example, the encapsulation layer TFE may mean a layer disposed at an uppermost portion of the panel layer PNL.

The encapsulation layer TFE may include a surface corresponding to a second surface S2 of the panel layer PNL. A top surface of the encapsulation layer TFE (e.g., in the third direction DR3) may correspond to the second surface S2. The second surface S2 may be a top surface of the panel layer PNL. The second surface S2 may be a surface (e.g., a front surface) on which a display image generated by the display device DD is displayed. The second surface S2 may be a surface disposed in the opposite direction (e.g., in the third direction DR3) of the first surface S1.

The structure of the display element layer DPL in accordance with an embodiment of the present disclosure is not necessarily limited thereto. Moreover, in some embodiments, the panel layer PNL may further include a sensor layer disposed on the display element layer DPL (e.g., on the encapsulation layer TFE in the third direction DR3).

The window WD may be disposed on the second surface S2 of the panel layer PNL (e.g., disposed directly thereon in the third direction DR3). The window WD is a protective member disposed at an outer portion of the display device DD, and may be a substantially transparent transmissive substrate. In an embodiment, the window WD may have a multi-layer structure selected from a glass substrate, a plastic film, and a plastic substrate. The window WD may include a rigid or flexible substrate, and the material constituting the window WD is not necessarily limited to a particular material and may vary.

In an embodiment, the display device DD may further include various structures such as a polarizing plate (or another kind of anti-reflection layer) for external light prevention between the window WD and the panel layer PNL (e.g., in the third direction DR3).

The display device DD in an embodiment of the present disclosure has an excellent strain rate (e.g., a rate at which a component is stretched when the component is bent), and is characterized in that a defect rate of the display device DD is decreased. For example, the display device DD in accordance with an embodiment of the present disclosure may have a strain rate greater than or equal to about 1.5% when the display device DD is bent.

To decrease the defect rate of the display device DD, the display device DD in accordance with an embodiment of the present disclosure may have a thickness (e.g., length in the third direction DR3) in a range of about 1 μm to about 8.8 μm in an area in which the encapsulation layer TFE overlaps with the bending area BDA in a plan view. In a comparative embodiment, in the area in which the encapsulation layer TFE overlaps with the bending area BDA, when the display device DD is formed with a thickness of less than about 1 μm, it may be difficult to suitably cover the panel layer PNL. In the area in which the encapsulation layer TFE overlaps with the bending area BDA, when the display device DD is formed with a thickness exceeding about 8.8 μm, the panel layer PNL may not be appropriately bent when the panel layer PNL is bent.

The display device DD may have structures of various encapsulation layers TFE in some embodiments.

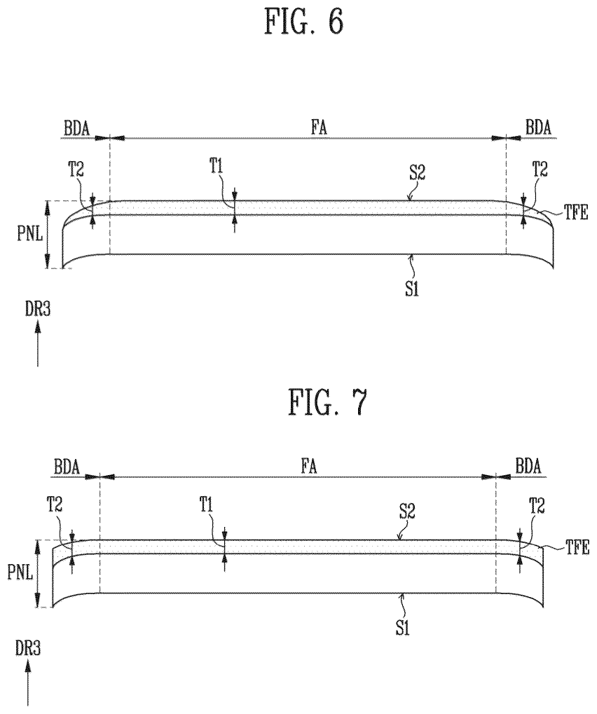

Hereinafter, encapsulation layers TFE in accordance with embodiments of the present disclosure will be described with reference to FIGS. 6 and 7. FIGS. 6 and 7 are schematic cross-sectional views of encapsulation layers in accordance with embodiments of the present disclosure. For clear and brief description, only the panel layer PNL is illustrated in FIGS. 6 and 7.

Referring to FIG. 6, an encapsulation layer TFE may be disposed in the front area FA and the bending area BDA. The encapsulation layer TFE may overlap with the front area FA and the bending area BDA in a plan view. For example, the encapsulation layer TFE may be disposed throughout (e.g., in an entirety of) the front area FA and the bending area BDA.

The encapsulation layer TFE may have a first thickness T1 (e.g., length in the third direction DR3) which is roughly uniform in an area in which the encapsulation layer TFE overlaps with the front area FA in a plan view. The first thickness T1 may be an average thickness of the encapsulation layer TFE in the area in which the encapsulation layer TFE overlaps with the front area FA in a plan view.

The encapsulation layer TFE may have a second thickness T2 (e.g., length in the third direction DR3) in an area in which the encapsulation layer TFE overlaps with the bending area BDA in a plan view. The second thickness T2 may be an average thickness of the encapsulation layer TFE in the area in which the encapsulation layer TFE overlaps with the bending area BDA in a plan view. Hereinafter, in the disclosure, a plane may be defined as a plane on which the panel layer PNL (or the base layer BSL) is disposed.

In an embodiment, the first thickness T1 and the second thickness T2 may be different from each other. For example, the first thickness T1 may be greater than the second thickness T2. The encapsulation layer TFE may have a roughly uniform thickness in the front area FA, and have a thickness which decreases as it approaches the outer portion of the display device DD in the bending area BDA.

In some embodiments, the first thickness T1 may be in a range of about 8.8 μm to about 15 μm. In some embodiments, the second thickness T2 may be in a range of about 1 μm to about 8.8 μm.

The encapsulation layer TFE may have the second thickness T2 of about 1 μm to 8.8 μm in the area in which the encapsulation layer TFE overlaps with the bending area BDA in a plan view, and have a strain rate greater than or equal to about 1.5% when the display device DD is bent. Experimentally, a strain rate of a minimum of about 1.2% may be required such that the display device DD is bent in the bending area BDA. For example, the display device DD in accordance with the disclosure may have a strain rate greater than or equal to about 1.5%, and the panel layer PNL may be appropriately bent in the bending area BDA.

Referring to FIG. 7, an embodiment shown in FIG. 7 is different from the embodiment shown in FIG. 6, in that a first thickness T1 and a second thickness T2 of the encapsulation layer TFE are the same. Thus, the encapsulation layer TFE may have a roughly uniform thickness.

In some embodiments, each of the first thickness T1 and the second thickness T2 may be in a range of about 1 μm to about 8.8 μm. In an embodiment shown in FIG. 7, the encapsulation layer TFE may have the second thickness T2 in a range of about 1 μm to about 8.8 μm in an area in which the encapsulation layer TFE overlaps with the bending area BDA in a plan view, and have a strain rate greater than or equal to about 1.5% when the display device DD is bent.

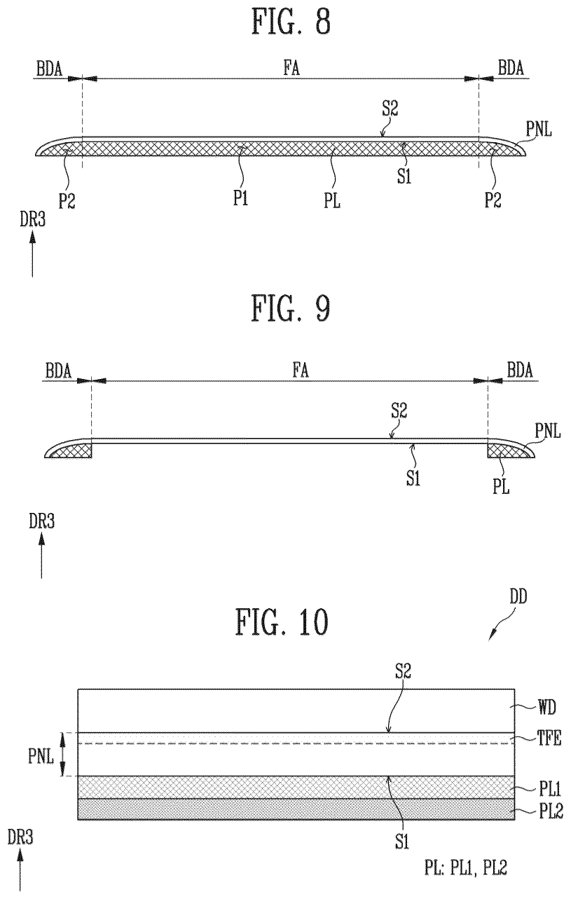

Hereinafter, support layers PL in accordance with embodiments of the present disclosure will be described with reference to FIGS. 8 and 9. The display device DD may have structures of different support layers PL in some embodiments. FIGS. 8 and 9 are schematic cross-sectional views of support layers in accordance with embodiments of the present disclosure. FIGS. 8 and 9 may be views illustrating a cross-section of the support layer PL in accordance with an embodiment shown in FIG. 4. For clear and brief description, only the panel layer PNL and the support layer PL are illustrated in FIGS. 8 and 9. In an embodiment, each of the support layers PL in accordance with embodiments shown in FIGS. 8 and 9 is formed as a single layer.

In the display device DD in accordance with an embodiment of the present disclosure, the support layer PL may have a roughly uniform storage modulus in a range of 0.01 about Mpa to about 0.1 Mpa within the support layer PL (or in an area in which the support layer PL overlaps with the bending area BDA in some embodiments), and have a strain rate greater than or equal to about 1.5% when the display device DD is bent. In addition, the display device DD in accordance with an embodiment of the present disclosure may reduce a risk that cracks will occur in the support layer PL when the panel layer PNL is bent.

Referring to FIG. 8, a support layer PL may entirely overlap with the front area FA and the bending area BDA in a plan view. The support layer PL may include a first portion P1 and the second portion P2.

The first portion P1 may overlap with the front area FA in a plan view. The second portion P2 may overlap with the bending area BDA in a plan view. The support layer PL may be formed in the front area FA and the bending area BDA. For example, in an embodiment the support layer PL may be formed throughout (e.g., in an entirety of) the front area FA and the bending area BDA. The support layer PL may entirely overlap with the panel layer PNL in a plan view. For example, the support layer PL may overlap with an entirety of the panel layer PNL (e.g., in the third direction DR3).

The first portion P1 and the second portion P2 may include a same material as each other. For example, in some embodiments, the first portion P1 and the second portion P2 may be integrally formed. In some embodiments, the first portion P1 and the second portion P2 may include the same material by having a same composition. However, embodiments of the present disclosure are not necessarily limited thereto.

In some embodiments, the first portion P1 and the second portion P2 may include different materials from each other. Alternatively, in some embodiments, the first portion P1 and the second portion P2 may include the same material, and at least one material may be included by different compositions in the first portion P1 and the second portion P2.

The support layer PL (e.g., the first portion P1 and the second portion P2 of the support layer PL) may include an organic material and an inorganic material. For example, the support layer PL may include an organic material capable of supporting the panel layer PNL, and include an organic material capable of performing at least one of a light blocking function and a heat dissipation function. The support layer PL may perform an impact resistance function according to a composition of materials.

For example, in an embodiment the organic material may include at least one of silicon-based resin, phenol-based resin, acryl-based resin, methacryl-based resin, vinyl-based resin, epoxy-based resin, urethane-based resin, cellulose-based resin, parylene-based resin, and polyisoprene-based resin. For example, in an embodiment the inorganic material may include at least one of a light blocking material and a heat dissipation material. For example, the light blocking material may include a black pigment. For example, the black pigment may include at least one of carbon black, graphene, carbon nano tubes, and fullerene. For example, the heat dissipation material may include a metal or a metal nano particle. For example, in an embodiment the metal or the metal nano particle may include at least one compound selected from Ag, Cu, Al, Al₂O₃, Mg, Ti, and Au.

As the support layer PL in accordance with an embodiment of the present disclosure simultaneously includes the organic material capable of supporting the panel layer PNL and the inorganic material capable performing at least one of the light blocking function and the heat dissipation function, the support layer PL may be formed as a single layer. Conventionally, a layer for supporting a panel and a functional layer for performing the light blocking function and the heat dissipation function were separately formed. In the display device DD in accordance with an embodiment of the present disclosure, as at least one of the light blocking function and the heat dissipation function is added to the support layer PL, the number of adhesive layers formed to achieve interlayer adhesion can be decreased, and the thickness of the display device DD can be decreased.

In an embodiment, the support layer PL may have a storage modulus in a range of about 0.01 Mpa to about 0.1 Mpa within the support layer PL. The support layer PL may have excellent impact resistance. The support layer PL may be bent when the panel layer PNL is bent, and sufficiently support the panel layer PNL. In a comparative embodiment in which the support layer PL has a storage modulus of less than about 0.01 Mpa, the viscosity of the support layer PL may be increased, and therefore, the support layer PL cannot sufficiently support the panel layer PNL. In a comparative embodiment in which the support layer PL has a storage modulus exceeding about 0.1 Mpa, the support layer PL may have a high Young's modulus, and a defect such as cracks may occur in the support layer PL when the support layer PL is bent.

For example, conventionally, as the support layer PL included only polyethylene terephthalate, the support layer PL was formed on the panel layer PNL to entirely overlap with the front area FA and the bending area BDA in a plan view, and had a Young's modulus of about 4 Gpa. Accordingly, when the support layer PL was bent in the bending area BDA, the support layer PL was not sufficiently bent, and therefore, cracks occurred. As compared with this, the display device DD in accordance with an embodiment of the present disclosure has a storage modulus in a range of about 0.01 Mpa to about 0.1 Mpa, and the defect rate of the display device DD can be decreased.

In some embodiments, the support layer PL may be formed by being applied on the first surface S1 of the panel layer PNL and then cured. In an embodiment, the support layer PL may be applied on the first surface S1 of the panel layer PNL through a printing process. For example, the printing process may include an inkjet printing process, a screen printing process, an imprint printing process, or a dispenser printing process. In some embodiments, the support layer PL may be formed through the printing process, and the width of the non-display area NDA may be decreased as the support layer PL is relatively easily formed in a desired area.

In some embodiments, as the support layer PL may be formed through the printing process, the support layer PL may be formed immediately on the panel layer PNL. For example, the support layer PL may be disposed directly on the panel layer PNL. For example, in an embodiment an adhesive layer between the support layer PL and the panel layer PNL may be omitted. In an embodiment in which the adhesive layer between the support layer PL and the panel layer PNL is omitted, the thickness of the display device DD can be decreased, and manufacturing processes of the display device DD can simplified, thereby reducing the manufacturing cost of the display device DD.

Referring to FIG. 9, the first portion P1 of the support layer PL shown in FIG. 8 may be omitted. An embodiment shown in FIG. 9 is different from the embodiment shown in FIG. 8, in that a support layer PL is formed in only an area in which the support layer PL overlaps with the bending area BDA in a plan view. Hereinafter, descriptions of portions overlapping with those described above will be omitted.

In an embodiment, the support layer PL may not overlap with the front area FA in a plan view. The support layer PL may expose the front area FA.

In an embodiment, the support layer PL shown in FIG. 9 may also have a storage modulus in a range of about 0.01 Mpa to about 0.1 Mpa within the support layer PL. The support layer PL may support the panel layer PNL in an area in which the support layer PL overlaps with the bending area BDA in a plan view. As the support layer PL is formed in the area in which the support layer PL overlaps with the bending area BDA in a plan view, and has the storage modulus in a range of about 0.01 Mpa to about 0.1 Mpa, the support layer PL can be sufficiently bent when the panel layer PNL is bent.

In the above, although an embodiment in which the support layer PL is formed as a single layer is illustrated, embodiments of the present disclosure are not necessarily limited thereto. Hereinafter, an embodiment in which the support layer PL is formed as a multi-layer will be described with reference to FIGS. 10 to 12.

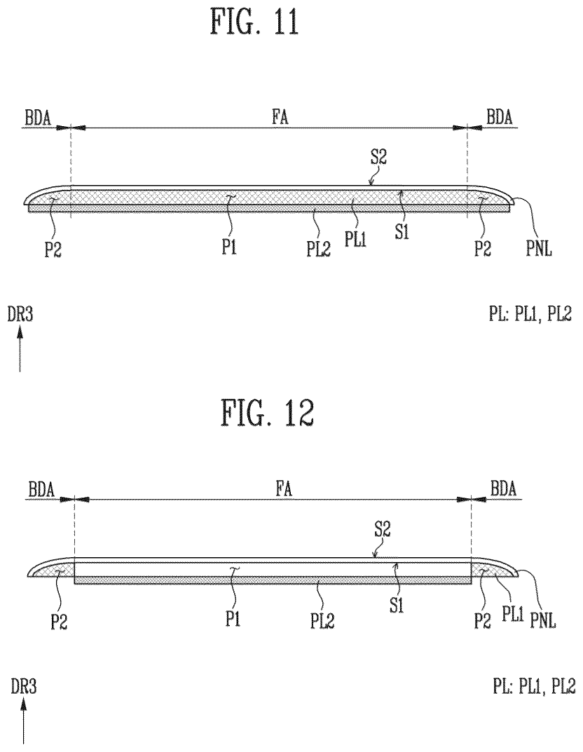

FIG. 10 is a cross-sectional view schematically illustrating a stacked structure of the display device in accordance with an embodiment of the present disclosure. FIGS. 11 and 12 are schematic cross-sectional views of support layers in accordance with embodiments of the present disclosure. FIGS. 11 and 12 may be views illustrating a cross-section of a support layer PL in accordance with an embodiment shown in FIG. 10. For clear and brief description, only the panel layer PNL and the support layer PL are illustrated in FIGS. 11 and 12. Each of the support layers PL in accordance with the embodiments shown in FIGS. 11 and 12 is formed as a multi-layer. Hereinafter, for convenience, an embodiment in which the support layer PL is formed as a double layer is described. However, embodiments of the present disclosure are not necessarily limited thereto, and the number of the plurality of support layers PL may be three or more in some embodiments.

Referring to FIG. 10, the support layer PL may include a first support layer PL1 and a second support layer PL2. The first support layer PL1 may be disposed on the first surface S1 of the panel layer PNL (e.g., disposed directly thereon in the direction opposite to the third direction DR3). The second support layer PL2 may be disposed on the first support layer PL1 (e.g., disposed directly thereon in the direction opposite to the third direction DR3).

The first support layer PL1 may be disposed more adjacent to the panel layer PNL than the second support layer PL2. For example, the first support layer PL1 may be disposed between the panel layer PNL and the second support layer PL2 (e.g., in the third direction DR3).

Referring to FIG. 11, a first support layer PL1 may include a first portion P1 and a second portion P2. The first support layer PL1 may entirely overlap with the front area FA and the bending area BDA in a plan view. The first portion P1 may overlap with the front area FA in a plan view. The second portion P2 may overlap with the bending area BDA in a plan view. The first support layer PL1 may be formed in the front area FA and the bending area BDA. For example, the first support layer PL1 may be formed throughout (e.g., in an entirety of) the front area FA and the bending area BDA. The first support layer PL1 may entirely overlap with the panel layer PNL in a plan view.

In an embodiment, the first support layer PL1 may have a storage modulus in a range of about 0.01 Mpa to about 0.1 Mpa within the first support layer PL1. The first support layer PL1 may be sufficiently bent when the panel layer PNL is bent, and sufficiently support the panel layer PNL.

The first support layer PL1 may support the panel layer PNL. The first support layer PL may be transparent. In an embodiment, the first support layer PL1 may include an organic material. In some embodiments, the organic material may include at least one of silicon-based resin, phenol-based resin, acryl-based resin, methacryl-based resin, vinyl-based resin, epoxy-based resin, urethane-based resin, cellulose-based resin, parylene-based resin, and polyisoprene-based resin.

In an embodiment, a second support layer PL2 may be disposed on a bottom surface of the first support layer PL1 (e.g., disposed directly thereon in the direction opposite to the third direction DR3). The second support layer PL2 may entirely overlap with the first support layer PL1 in a plan view. The second support layer PL2 may overlap with an entirety of the first portion P1 and the second portion P2 in a plan view.

Although an embodiment in which the second support layer PL2 overlaps with the front area FA and the bending area BDA in a plan view is illustrated in FIG. 11, embodiments of the present disclosure are not necessarily limited thereto. For example, in some embodiments, the second support layer PL2 may overlap with the front area FA in a plan view, and may not overlap with the bending area BDA in a plan view.

In an embodiment, the second support layer PL2 may be formed after the first support layer PL1 and the panel layer PNL are bent. For example, the second support layer PL2 may be attached on the first support layer PL1 through a lamination process.

In an embodiment, the second support layer PL2 may have a light blocking characteristic, an impact resistance characteristic, and a heat dissipation characteristic. For example, the second support layer PL2 may be a functional layer having the light blocking characteristic, the impact resistance characteristic, and the heat dissipation characteristic. The second support layer PL2 may include at least one of a light blocking material and a heat dissipation material. For example, the light blocking material may include a black pigment. For example, in an embodiment the black pigment may include at least one of carbon black, graphene, carbon nano tubes, and fullerene. For example, the heat dissipation material may include a metal or a metal nano particle. For example, in an embodiment the metal or the metal nano particle may include at least one compound selected from Ag, Cu, Al, Al₂O₃, Mg, Ti, and Au.

Referring to FIG. 12, a second support layer PL2 may not overlap with the second portion P2 in a plan view. An embodiment shown in FIG. 12 is different from an embodiment shown in FIG. 11, in that the second support layer PL2 does not overlap with the second portion P2 in a plan view and that a first support layer PL1 has a storage modulus that is greater than about 0.1 Mpa at the first portion P1.

The first support layer PL1 may have a storage modulus greater than about 0.1 Mpa at the first portion P1. For example, in an embodiment the first portion P1 may include polyethylene terephthalate, and have a storage modulus greater than a storage modulus of the second portion P2. In an embodiment in which the first portion P1 includes polyethylene terephthalate, the storage modulus of the first portion P1 is relatively large as compared with an embodiment in which the first portion P1 includes another material, and can more firmly support the panel layer PNL.

In an embodiment, the second portion P2 may include an organic material and an inorganic material. For example, the second portion P2 may include an organic material capable of supporting the panel layer PNL, and include an organic material capable of performing at least one of a light blocking function and a heat dissipation function. The support layer PL may perform an impact resistance function according to a composition of materials.

In an embodiment, the second portion P2 may have a storage modulus in a range of about 0.01 Mpa to about 0.1 Mpa. The second portion P2 may be sufficiently bent when the panel layer PNL is bent, and sufficiently support the panel layer PNL.

The second support layer PL2 may be disposed on a bottom surface of the first support layer PL1 (e.g., disposed directly thereon in the direction opposite to the third direction DR3). In an embodiment, the second support layer PL2 may overlap with the first portion P1 of the first support layer PL1 in a plan view, and may not overlap with the second portion P2 of the first support layer PL1 in a plan view.

In an embodiment, the second support layer PL2 may be formed after the first support layer PL1 and the panel layer PNL are bent. For example, the second support layer PL2 may be attached on the first support layer PL1 through a lamination process.

As described above, the display device DD in accordance with an embodiment of the present disclosure may have a storage modulus in a range of about 0.01 Mpa to about 0.1 Mpa in an area in which at least a portion of the support layer PL (e.g., the support layer PL or the first support layer PL1) overlaps with the bending area BDA in a plan view, and reduce a risk that cracks will occur when at least a portion of the support layer PL is bent. Also, the display device DD in accordance with an embodiment of the present disclosure may have a thickness in a range of about 1 μm to about 8.8 μm in an area in which the encapsulation layer TFE overlaps with the bending area BDA, and have a strain rate greater than or equal to about 1.5% when the display device DD is bent.

In accordance with an embodiment of the present disclosure, a display device has a decreased defect rate.

Non-limiting embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure.

What is claimed is:

1. A display device comprising:
a panel layer including a first area and a second area; and
a support layer disposed on a first surface of the panel layer,
wherein at least a portion of the panel layer is bendable in the second area,
wherein the support layer overlaps with the second area in a plan view, and
wherein the support layer has a storage modulus in a range of about 0.01 Mpa to about 0.1 Mpa in an area that the support layer overlaps with the second area in the plan view.

2. The display device of claim 1, wherein:
the panel layer includes a second surface opposite to the first surface;
the panel layer includes an encapsulation layer including a surface corresponding to the second surface, and
wherein a display image generated by the display device is displayed on the second surface of the panel layer.

3. The display device of claim 2, wherein the encapsulation layer is disposed at an outermost portion of the panel layer.

4. The display device of claim 2, wherein the encapsulation layer has:
a first thickness in an area that the encapsulation layer overlaps with the first area in the plan view; and
a second thickness in an area that the encapsulation layer overlaps with the second area in the plan view, and
wherein the first thickness is in a range of about 8.8 μm to about 15 μm, and
the second thickness is in a range of about 1 μm to about 8.8 μm.

5. The display device of claim 2, wherein the encapsulation layer has:
a first thickness in an area that the encapsulation layer overlaps with the first area in the plan view; and
a second thickness equal to the first thickness in an area that the encapsulation layer overlaps with the second area in the plan view, and
wherein each of the first thickness and the second thickness is in a range of about 1 μm to about 8.8 μm.

6. The display device of claim 1, wherein the support layer overlaps with the first area in the plan view.

7. The display device of claim 1, wherein the support layer does not overlap with the first area in the plan view.

8. The display device of claim 1, wherein:
the support layer includes an organic material; and
the support layer further includes at least one material selected from a heat dissipation material and a light blocking material.

9. The display device of claim 8, wherein the organic material includes at least one material selected from silicon-based resin, phenol-based resin, acryl-based resin, methacryl-based resin, vinyl-based resin, epoxy-based resin, urethane-based resin, cellulose-based resin, parylene-based resin, and polyisoprene-based resin,
wherein the heat dissipation material includes at least one compound selected from Ag, Cu, Al, Al₂O₃, Mg, Ti, and Au, and
wherein the light blocking material includes at least one of carbon black, graphene, carbon nano tubes, and fullerene.

10. The display device of claim 1, wherein the support layer is applied on the first surface through a printing process.

11. The display device of claim 1, wherein:
the support layer is applied and cured on the panel layer; and
the support layer is disposed directly on the panel layer.

12. A display device comprising:
a panel layer including a first area and a second area;
a support layer disposed on a first surface of the panel layer; and
a window disposed on a second surface of the panel layer opposite to the first surface of the panel layer,
wherein the panel layer includes an encapsulation layer including a surface corresponding to the second surface,
wherein at least a portion of the panel layer is bendable in the second area,
wherein the support layer overlaps with the second area in a plan view, and
wherein the encapsulation layer has a thickness in a range of about 1 μm to about 8.8 μm in an area that the encapsulation layer overlaps with the second area in the plan view.

13. The display device of claim 12, wherein the encapsulation layer is disposed at an outermost portion of the panel layer.

14. The display device of claim 12, wherein the support layer has a storage modulus in a range of about 0.01 Mpa to about 0.1 Mpa in an area that the support layer overlaps with the second area, and
wherein the support layer overlaps with both the first area and the second area in the plan view.

15. The display device of claim 12, wherein the support layer has a storage modulus in a range of about 0.01 Mpa to about 0.1 Mpa in an area that the support layer overlaps with the second area in the plan view, and
wherein the support layer does not overlap with the first area in the plan view.

16. The display device of claim 12, wherein:
the support layer includes an organic material, and further includes at least one of a heat dissipation material and a light blocking material,
wherein the organic material includes at least one material selected from silicon-based resin, phenol-based resin, acryl-based resin, methacryl-based resin, vinyl-based resin, epoxy-based resin, urethane-based resin, cellulose-based resin, parylene-based resin, and polyisoprene-based resin,
wherein the heat dissipation material includes at least one compound selected from Ag, Cu, Al, Al₂O₃, Mg, Ti, and Au, and
wherein the light blocking material includes at least one of carbon black, graphene, carbon nano tubes, and fullerene.

17. The display device of claim 12, wherein the support layer is applied on the first surface through a printing process, the support layer is disposed directly on the panel layer.

18. A display device comprising:
a panel layer including a first area and a second area;
a support layer disposed on a first surface of the panel layer; and
a window disposed on a second surface of the panel layer opposite to the first surface of the panel layer,
wherein the panel layer includes an encapsulation layer including a surface corresponding to the second surface,
wherein at least a portion of the panel layer is bendable in the second area,
wherein the support layer includes:
a first support layer disposed on the first surface; and
a second support layer disposed on the first support layer,
wherein the second support layer includes at least one of a light blocking material and a heat dissipation material,
wherein the support layer has a storage modulus in a range of about 0.01 Mpa to about 0.1 Mpa in an area that the support layer overlaps with the second area in a plan view, and
wherein the encapsulation layer has a thickness in a range of about 1 μm to about 8.8 μm in an area that the encapsulation layer overlaps with the second area in the plan view.

19. The display device of claim 18, wherein the second support layer is attached on the first support layer through a lamination process after the first support layer is bent.

20. The display device of claim 18, wherein the first support layer includes:
a first portion overlapping with the first area in the plan view; and
a second portion overlapping with the second area in the plan view,
wherein the first portion includes polyethylene terephthalate, and
wherein the panel layer has a flat surface in the first area.
